(19) United States
(12) Patent Application Publication
(10) Pub. No.: US 2021/0356824 A1
(43) Pub. Date: Nov. 18, 2021

(54) COA ARRAY SUBSTRATE AND METHOD OF FABRICATING SAME

(71) Applicant: Shenzhen China Star Optoelectronics Semiconductor Display Technology Co., Ltd., Shenzhen (CN)

(72) Inventor: Lanyan LI, Shenzhen (CN)

(21) Appl. No.: 16/625,699

(22) PCT Filed: Nov. 21, 2019
(86) PCT No.: PCT/CN2019/119942

§ 371 Date: Dec. 21, 2019

(30) Foreign Application Priority Data
Nov. 7, 2019 (CN) 201911079382.0

(51) Int. Cl. G02F 1/1362; G02F 1/1368; H01L 27/12

(52) U.S. Cl. CPC G02F 1/136227; G02F 1/136222; H01L 27/1259; H01L 27/124; H01L 27/1248; G02F 1/1368

(57) ABSTRACT

A color-filter-on-array (COA) array substrate and a method of fabricating the same are provided. The COA array substrate has: a base substrate; a thin film transistor (TFT) array structure disposed on the base substrate; a first protective layer disposed on the TFT array structure; a color photoresist layer disposed on the first protective layer; a second protective layer disposed on the color photoresist layer, wherein a through hole pass through the second protective layer, the color photoresist layer, and the first protective layer; a conductive layer disposed on the second protective layer and in the through hole, wherein the conductive layer is electrically connected to the TFT array structure; and a spacing layer disposed on the conductive layer and filled in the through hole. The COA array substrate can avoid problems of twill traces and rising product costs.

### FIELD OF DISCLOSURE

The present disclosure relates to an array substrate and a method of fabricating the same, and more particularly to a color-filter-on-array (COA) array substrate and a method of fabricating the same

### BACKGROUND OF DISCLOSURE

A liquid crystal panel includes an array substrate, a color filter substrate, and a liquid crystal layer sandwiched between the array substrate and the color filter substrate. Among them, an electric field is generated by a circuit to drive liquid crystal molecules, so that the liquid crystal has different optical effects.

A color-filter-on-array (COA) technology is a technology for fabricating a color filter on a side of a thin film transistor (TFT) to reduce parasitic capacitance and increase product aperture ratio. In addition, many companies have combined a use of COA and a polymer-film-on-array (PFA) technology to further improve the aperture ratio. However, this design also leads to an increase in depth of via holes of the substrate, which easily cause problems in subsequent coating of the polyimide (PI) thin film, resulting in uneven light in the display panel, so as to produce twill traces (also known as mura). In addition, as depth of the through hole increases, more liquid crystal molecules need to be filled into the through hole so as to achieve a same effect, so the product cost increases.

Therefore, it is necessary to provide a COA array substrate and a method of fabricating the same to solve the problems existing in the conventional technologies.

### SUMMARY OF DISCLOSURE

From above, the present disclosure provides a color-filter-on-array (COA) array substrate and a method of fabricating the same to solve problems, existing in the conventional technologies, of twill traces (also known as mura) and rising product costs in the prior art.

An object of the present disclosure is to provide a COA array substrate and a method for manufacturing the same, by filling a spacing layer in a through hole to avoid problems of twill traces and rising product cost.

To achieve the above object of the present disclosure, an embodiment of the present disclosure provides a COA array substrate comprising a base substrate, a thin film transistor (TFT) array structure, a first protective layer, a color photoresist layer, a second protective layer, a conductive layer, and a spacing layer. The TFT array structure is disposed on the base substrate. The first protective layer is disposed on the TFT array structure, wherein material of the first protective layer comprises an insulating material. The color photoresist layer is disposed on the first protective layer. The second protective layer is disposed on the color photoresist layer, wherein a through hole passes through the second protective layer, the color photoresist layer, and the first protective layer. The conductive layer is disposed on the second protective layer and in the through hole, wherein the conductive layer is electrically connected to the TFT array structure. The spacing layer is disposed on the conductive layer and filled in the through hole, wherein the spacing layer filled in the through hole and the conductive layer form a flat surface.

In an embodiment of the present disclosure, material of the second protective layer comprises at least one of an organic insulating material and an inorganic insulating material.

In an embodiment of the present disclosure, the TFT array structure comprises a gate layer, a gate insulating layer, and an active layer. The gate layer is disposed on the base substrate. The gate insulating layer is disposed on the gate layer. The active layer is disposed on the gate insulating layer, wherein the active layer comprises a source doped region, a drain doped region, and a channel region, and the channel region is disposed between the source doped region and the drain doped region, and the conductive layer is electrically connected to the drain doped region through the through hole.

To achieve the above object of the present disclosure, an embodiment of the present disclosure provides a COA array substrate comprising a base substrate, a thin film transistor (TFT) array structure, a first protective layer, a color photoresist layer, a second protective layer, a conductive layer, and a spacing layer. The TFT array structure is disposed on the base substrate. The first protective layer is disposed on the TFT array structure. The color photoresist layer is disposed on the first protective layer. The second protective layer is disposed on the color photoresist layer, wherein a through hole passes through the second protective layer, the color photoresist layer, and the first protective layer. The conductive layer is disposed on the second protective layer and in the through hole, wherein the conductive layer is electrically connected to the TFT array structure. The spacing layer is disposed on the conductive layer and filled in the through hole.

In an embodiment of the present disclosure, the spacing layer filled in the through hole and the conductive layer form a flat surface.

In an embodiment of the present disclosure, material of the first protective layer comprises an insulating material.

In an embodiment of the present disclosure, material of the second protective layer comprises at least one of an organic insulating material and an inorganic insulating material.

In an embodiment of the present disclosure, the TFT array structure comprises a gate layer, a gate insulating layer, and an active layer. The gate layer is disposed on the base substrate. The gate insulating layer is disposed on the gate layer. The active layer is disposed on the gate insulating layer, wherein the active layer comprises a source doped region, a drain doped region, and a channel region, and the channel region is disposed between the source doped region and the drain doped region, and the conductive layer is electrically connected to the drain doped region through the through hole.

Further, another embodiment of the present disclosure provides a method of fabricating a COA array substrate, comprising steps of: providing a base substrate; forming a thin film transistor (TFT) array structure on the base substrate; forming a first protective layer on the TFT array structure; forming a color photoresist layer on the first protective layer; forming a second protective layer on the color photoresist layer; forming a through hole passing through the second protective layer, the color photoresist layer, and the first protective layer; forming a conductive layer on the second protective layer and in the through hole, wherein the conductive layer is electrically connected to the TFT array structure; and forming a spacing layer on the conductive layer and filling the spacing layer in the through hole.

In an embodiment of the present disclosure, the spacing layer filled in the through hole and the conductive layer form a flat surface.

In an embodiment of the present disclosure, material of the first protective layer comprises an insulating material.

In an embodiment of the present disclosure, material of the second protective layer comprises at least one of an organic insulating material and an inorganic insulating material.

In an embodiment of the present disclosure, the spacing layer is formed by a half-tone photomask or a gray-tone photomask.

Compared with the conventional technologies, the COA array substrate and the method of fabricating the same in the present disclosure avoid the problems of twill traces and rising product costs by filling a spacing layer in the through hole.

To make the above description of the present disclosure more clearly comprehensible, it is described in detail below in examples of preferred embodiments with the accompanying drawings.

### DESCRIPTION OF DRAWINGS

FIG. 1 is a schematic cross-sectional view of a COA array substrate according to an embodiment of the present disclosure.

FIG. 2 is a schematic flowchart of a method of fabricating a COA array substrate according to an embodiment of the present disclosure.

### DETAILED DESCRIPTION OF PREFERRED EMBODIMENTS

Following description of the various embodiments is provided to illustrate the specific embodiments of the present disclosure. Furthermore, directional terms mentioned in the present disclosure, such as upper, lower, top, bottom, front, rear, left, right, inner, outer, side, surrounding, central, horizontal, horizontal, vertical, longitudinal, axial, radial, an uppermost layer or a lowermost layer, etc., only refer to a direction of the accompanying figures. Therefore, the used directional terms are used to describe and understand the present disclosure, but the present disclosure is not limited thereto.

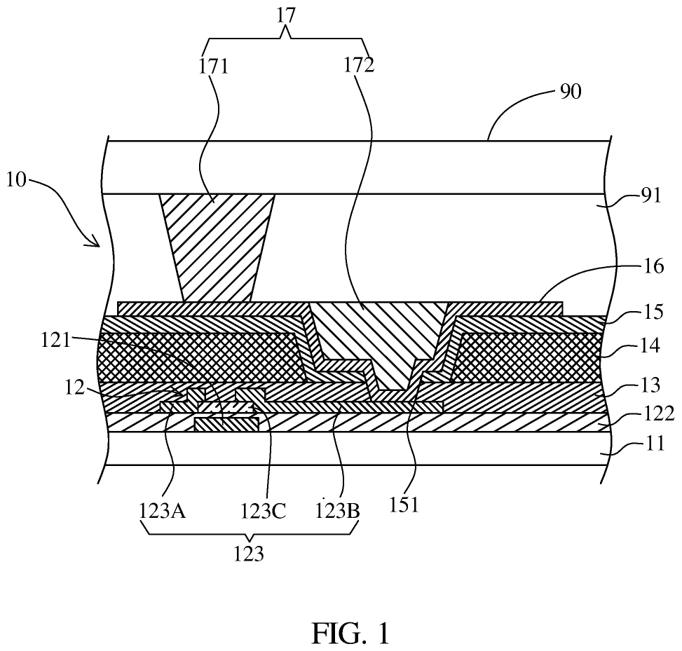

Referring to FIG. 1, an embodiment of the present disclosure provides a color-filter-on-array (COA) array substrate 10 comprising a base substrate 11, a thin film transistor (TFT) array structure 12, a first protective layer 13, a color photoresist layer 14, a second protective layer 15, a conductive layer 16, and a spacing layer 17. In an embodiment, the base substrate 11 can be used to support the TFT array structure 12, the first protective layer 13, the color photoresist layer 14, the second protective layer 15, the conductive layer 16, and the spacing layer 17. In an embodiment, the base substrate 11 is, for example, a flexible substrate, a transparent substrate, or a flexible transparent substrate.

In the embodiment of the present disclosure, the TFT array structure 12 of the COA array substrate 10 is disposed on the base substrate 11. In an embodiment, the TFT array structure 12 includes: a gate layer 121, a gate insulating layer 122, and an active layer 123. The gate layer 121 is disposed on the base substrate 11. The gate insulating layer 122 is disposed on the gate layer 121. The active layer 123 is disposed on the gate insulating layer 122. The active layer 123 includes a source doped region 123A, a drain doped region 123B, and a channel region 123C. The channel region 123C is disposed between the source doped region 123A and the drain doped region 123B.

In an embodiment of the present disclosure, the first protective layer 13 of the COA array substrate 10 is disposed on the TFT array structure 12. The first protective layer 13 is mainly used to protect the TFT array structure 12. In an embodiment, the first protective layer 13 includes an insulating material.

In one example, the first protective layer 13 includes at least one of an organic insulating material and an inorganic insulating material.

In an embodiment of the present disclosure, the color photoresist layer 14 of the COA array substrate 10 is disposed on the first protective layer 13. In an embodiment, the color photoresist layer 14 includes at least one of a red photoresist, a green photoresist, and a blue photoresist.

In an embodiment of the present disclosure, the second protective layer 15 of the COA array substrate 10 is disposed on the color photoresist layer 14, and a through hole 151 passes through the second protective layer 15, the color photoresist layer 14, and the first protective layer 13. In an embodiment, material of the second protective layer 15 includes at least one of an organic insulating material and an inorganic insulating material.

In an embodiment of the present disclosure, the conductive layer 16 of the COA array substrate 10 is disposed on the second protective layer 15 and in the through hole 151. In an embodiment, material of the conductive layer 16 includes indium tin oxide (ITO). In another embodiment, the conductive layer 16 is electrically connected to the drain doped region 123B through the through hole 151. In another embodiment, depth of the through hole 151 is between 2.5 and 4.0 micrometers.

In an embodiment of the present disclosure, the spacing layer 17 of the COA array substrate 10 is disposed on the conductive layer 16 and is filled in the through hole 151. It should be mentioned here that the spacing layer 17 includes a portion 171 (that is, disposed on the conductive layer 16) for a spacing effect and a portion 172 (that is, filled in the through hole 151) for a filling effect. It should be mentioned that the portion 172 as the filling effect can be filled in the through hole 151, thereby reducing a filling amount of liquid crystal molecules, and also avoiding generation of mura (because the through hole 151 is filled, a polyimide (PI) thin film can be coated uniformly). In a specific example, the spacing layer 17 filled in the through hole 151 and the conductive layer 16 form a flat surface.

It can be known from the above that the COA array substrate according to an embodiment of the present disclosure at least is that, when the spacing layer 17 is formed, the portion 172 for the filling effect is also formed in addition to form the portion 171 for the spacing effect. In an embodiment, the portion 171 and the portion 172 can be formed in a same process (for example, through a half-tone photomask or a grey dimming mask), so the fabricating cost can be saved. In an example, the portion 171 is formed by receiving a partial ultraviolet exposure, and the portion 172 is formed by receiving a complete ultraviolet exposure.

In an embodiment, the COA array substrate 10 according to an embodiment of the present disclosure can be assembled on an opposite substrates 90, and a liquid crystal layer 91 is filled between the COA array substrate 10 and the opposite substrate 90, such that a display panel is formed.

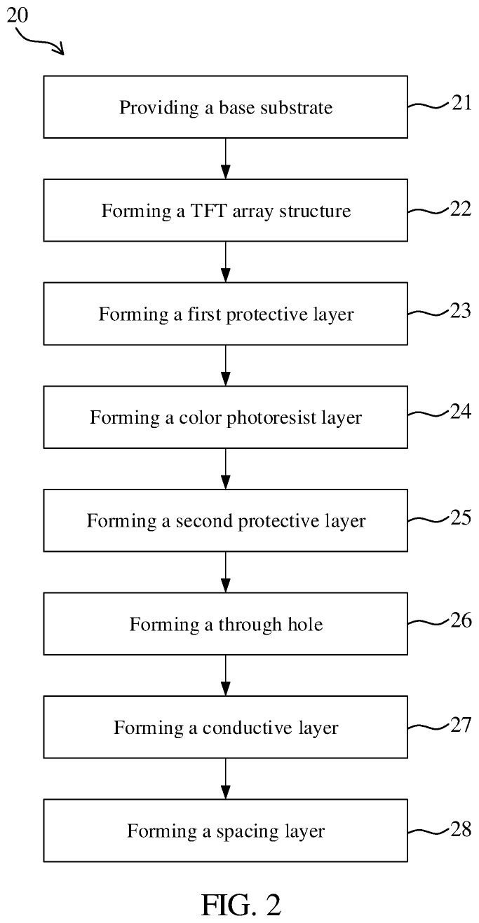

Referring to FIG. 2, a method 20 of fabricating a COA array substrate according to an embodiment of the present disclosure includes steps 21 to 28: providing a base substrate (step 21); forming a thin film transistor (TFT) array structure on the base substrate (step 22); forming a first protective layer on the TFT array structure (step 23); forming a color photoresist layer on the first protective layer (step 24); forming a second protective layer on the color photoresist layer (step 25); forming a through hole passing through the second protective layer, the color photoresist layer, and the first protective layer (step 26); forming a conductive layer on the second protective layer and in the through hole, wherein the conductive layer is electrically connected to the TFT array structure (step 27); and forming a spacing layer on the conductive layer and filling the spacing layer in the through hole (step 28).

Referring to FIG. 1 and FIG. 2, in an embodiment of the present disclosure, the method 20 of fabricating the COA array substrate has a step 21 of providing a base substrate 11. In an embodiment, the base substrate 11 can be used to support the TFT array structure 12, the first protective layer 13, the color photoresist layer 14, the second protective layer 15, the conductive layer 16, and the spacing layer 17. In an embodiment, the base substrate 11 is, for example, a flexible substrate, a transparent substrate, or a flexible transparent substrate.

In an embodiment of the present disclosure, the method 20 of fabricating the COA array substrate has a step 22 of forming a TFT array structure on the base substrate. In an embodiment, the TFT array structure 12 includes: a gate layer 121, a gate insulating layer 122, and an active layer 123. The gate layer 121 is disposed on the base substrate 11. The gate insulating layer 122 is disposed on the gate layer 121. The active layer 123 is disposed on the gate insulating layer 122. The active layer 123 includes a source doped region 123A, a drain doped region 123B, and a channel region 123C. The channel region 123C is disposed between the source doped region 123A and the drain doped region 123B. It should be mentioned that materials and fabricating methods of the TFT array structure 12 can refer to common materials or fabricating methods in general semiconductor processes.

In an embodiment of the present disclosure, the method 20 of fabricating the COA array substrate has a step 23 of forming a first protective layer on the TFT array structure. In an embodiment, the first protective layer 13 is mainly used to protect the TFT array structure 12. In an embodiment, the first protective layer 13 includes an insulating material. In one example, the first protective layer 13 includes at least one of an organic insulating material and an inorganic insulating material. It should be mentioned that, materials and fabricating methods of the first protective layer 13 can refer to common materials or fabricating methods in general semiconductor processes.

In an embodiment of the present disclosure, the method 20 of fabricating the COA array substrate has a step 24 of forming a color photoresist layer on the first protective layer. In an embodiment, the color photoresist layer 14 includes at least one of a red photoresist, a green photoresist, and a blue photoresist. It should be mentioned that, materials and fabricating methods of the color photoresist layer 14 can refer to common materials or fabricating methods in general semiconductor processes.

In an embodiment of the present disclosure, the method 20 of fabricating the COA array substrate has a step 25 of forming a second protective layer on the color photoresist layer. In an embodiment, material of the second protective layer 15 includes at least one of an organic insulating material and an inorganic insulating material. It should be mentioned that, fabricating methods of the second protective layer 15 can refer to fabricating methods in general semiconductor processes.

In an embodiment of the present disclosure, the method 20 of fabricating the COA array substrate has a step 26 of forming a through hole passing through the second protective layer, the color photoresist layer, and the first protective layer. In an embodiment, a position of the through hole 151 is aligned with a position of the drain doped region 123B of the TFT array structure 12. In another embodiment, depth of the through hole 151 is between 2.5 and 4.0 micrometers. It should be mentioned that, fabricating methods of the through hole can refer to fabricating methods in general semiconductor processes.

In an embodiment of the present disclosure, the method 20 of fabricating the COA array substrate has a step 27 of forming a conductive layer on the second protective layer and in the through hole, wherein the conductive layer is electrically connected to the TFT array structure. In an embodiment, material of the conductive layer 16 includes indium tin oxide (ITO). In an embodiment, the conductive layer 16 is electrically connected to the drain doped region 1238 of the TFT array structure 12. It should be mentioned that, materials and fabricating methods of the conductive layer 16 can refer to common materials or fabricating methods in general semiconductor processes.

In an embodiment of the present disclosure, the method 20 of fabricating the COA array substrate has a step 28 of forming a spacing layer on the conductive layer and filling the spacing layer in the through hole. In step 28, the spacing layer 17 includes a portion 171 (that is, disposed on the conductive layer 16) for a spacing effect and a portion 172 (that is, filled in the through hole 151) for a filling effect. It should be mentioned that the portion 172 as the filling effect can be filled in the through hole 151, thereby reducing a filling amount of liquid crystal molecules, and also avoiding generation of mura (because the through hole 151 is filled, a PI thin film can be coated uniformly). In a specific example, the spacing layer 17 filled in the through hole 151 and the conductive layer 16 form a flat surface.

It can be known from the above that the method 20 of fabricating the COA array substrate is mainly that, when the spacing layer 17 is formed, the portion 172 for the filling effect is also formed in addition to form the portion 171 for the spacing effect. In an embodiment, the portion 171 and the portion 172 can be formed in a same process (for example, through a half-tone photomask or a grey dimming mask), so the fabricating cost can be saved. In an example, the portion 171 is formed by receiving a partial ultraviolet exposure, and the portion 172 is formed by receiving a complete ultraviolet exposure.

In an embodiment, the COA array substrate 10 according to an embodiment of the present disclosure can be fabricated by the method 20 of fabricating the COA array substrate according to an embodiment of the present disclosure.

The present disclosure has been described in relative embodiments described above, but the above embodiments are merely examples for implementing the present disclosure. It is noted that the disclosed embodiments do not limit the scope of the disclosure. On the contrary, modifications and equal settings included in the spirit and scope of the claims are all included in the scope of the present disclosure.

1. A color-filter-on-array (COA) array substrate, comprising:
a base substrate;
a thin film transistor (TFT) array structure disposed on the base substrate;
a first protective layer disposed on the TFT array structure, wherein material of the first protective layer comprises an insulating material;
a color photoresist layer disposed on the first protective layer;
a second protective layer disposed on the color photoresist layer, wherein a through hole passes through the second protective layer, the color photoresist layer, and the first protective layer;
a conductive layer disposed on the second protective layer and in the through hole, wherein the conductive layer is electrically connected to the TFT array structure; and
a spacing layer disposed on the conductive layer and filled in the through hole, wherein the spacing layer filled in the through hole and the conductive layer form a flat surface.

2. The COA array substrate according to claim 1, wherein material of the second protective layer comprises at least one of an organic insulating material and an inorganic insulating material.

3. The COA array substrate according to claim 1, wherein the TFT array structure comprises:
a gate layer disposed on the base substrate;
a gate insulating layer disposed on the gate layer; and
an active layer disposed on the gate insulating layer, wherein the active layer comprises a source doped region, a drain doped region, and a channel region, and the channel region is disposed between the source doped region and the drain doped region, and the conductive layer is electrically connected to the drain doped region through the through hole.

4. A color-filter-on-array (COA) array substrate, comprising:
a base substrate;
a thin film transistor (TFT) array structure disposed on the base substrate;
a first protective layer disposed on the TFT array structure;
a color photoresist layer disposed on the first protective layer;
a second protective layer disposed on the color photoresist layer, wherein a through hole passes through the second protective layer, the color photoresist layer, and the first protective layer;
a conductive layer disposed on the second protective layer and in the through hole, wherein the conductive layer is electrically connected to the TFT array structure; and
a spacing layer disposed on the conductive layer and filled in the through hole.

5. The COA array substrate according to claim 4, wherein the spacing layer filled in the through hole and the conductive layer form a flat surface.

6. The COA array substrate according to claim 4, wherein material of the first protective layer comprises an insulating material.

7. The COA array substrate according to claim 4, wherein material of the second protective layer comprises at least one of an organic insulating material and an inorganic insulating material.

8. The COA array substrate according to claim 4, wherein the TFT array structure comprises:
a gate layer is disposed on the base substrate;
a gate insulating layer disposed on the gate layer; and
an active layer is disposed on the gate insulating layer, wherein the active layer comprises a source doped region, a drain doped region, and a channel region, and the channel region is disposed between the source doped region and the drain doped region, and the conductive layer is electrically connected to the drain doped region through the through hole.

9. A method of fabricating a color-filter-on-array (COA) array substrate, comprising steps of:
providing a base substrate;
forming a thin film transistor (TFT) array structure on the base substrate;
forming a first protective layer on the TFT array structure;
forming a color photoresist layer on the first protective layer;
forming a second protective layer on the color photoresist layer;
forming a through hole passing through the second protective layer, the color photoresist layer, and the first protective layer;
forming a conductive layer on the second protective layer and in the through hole, wherein the conductive layer is electrically connected to the TFT array structure; and
forming a spacing layer on the conductive layer and filling the spacing layer in the through hole.

10. The method of fabricating the COA array substrate according to claim 9, wherein the spacing layer filled in the through hole and the conductive layer form a flat surface.

11. The method of fabricating the COA array substrate according to claim 9, wherein material of the first protective layer comprises an insulating material.

12. The method of fabricating the COA array substrate according to claim 9, wherein material of the second protective layer comprises at least one of an organic insulating material and an inorganic insulating material.

13. The method of fabricating the COA array substrate according to claim 9, wherein the spacing layer is formed by a half-tone photomask or a gray-tone photomask.
